(19) United States
(12) Patent Application Publication
(10) Pub. No.: US 2025/0393230 A1
(43) Pub. Date: Dec. 25, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuei-Yu Kao, Hsinchu (TW); Chun-Yu Lin, Yilan (TW); Yu-Shan Lu, Zhubei (TW); Chiung-Yu Cho, Hsinchu (TW)

(73) Assignee: Taiwan Semiconductor Manufacturing Company, Ltd., Hsinchu (TW)

(21) Appl. No.: 18/750,056

(22) Filed: Jun. 21, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018

(57) ABSTRACT

A semiconductor fabrication method includes: depositing a dielectric layer above shallow trench isolation (STI) features formed between a first fin and a second fin on a substrate that each include an epitaxial stack including at least one sacrificial epitaxial layer and at least one channel epitaxial layer, wherein dielectric layer reduces STI loss during subsequent etching operations; patterning a sacrificial gate stack on channel regions of the first fin; forming gate spacers, performing source/drain (S/D) etching operations on opposite sides of the sacrificial gate stack and forming inner gate spacers; forming an S/D region; forming a contact etch stop layer (CESL); and replacing the sacrificial gate stack with a metal gate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method 100 of semiconductor fabrication, in accordance with some embodiments.

FIGS. 2-3, 4A-4B, 5A-5C, 6A-6C, 7A-7C, 8A-8C, 9A-9D, 10A-10B, 11-12, 13A-13B, 14-15, and 16A-16B, are schematic diagrams that illustrate an example semiconductor device structure at various stages of fabrication, in accordance with some embodiments.

FIGS. 17A and 17B are schematic diagrams of an example semiconductor device at a stage of fabrication after forming a stop layer, in accordance with some embodiments.

FIGS. 18A and 18B are schematic diagrams depicting an example semiconductor device at a stage of fabrication after dummy gate patterning, in accordance with some embodiments.

FIGS. 19A and 19B are schematic diagrams of another example semiconductor device at a stage of fabrication after spacer deposition, S/D etch, and inner spacer deposition and etching, in accordance with some embodiments.

FIGS. 20A and 20B are schematic diagrams of an example semiconductor device at a stage of fabrication after metal gate replacement, in accordance with some embodiments.

FIGS. 21A and 21B are schematic diagrams of an example semiconductor device, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Various embodiments are discussed herein in a particular context, namely, for forming a semiconductor structure that includes a fin-like field-effect transistor (FinFET) device. The semiconductor structure, for example, may be a complementary metal-oxide-semiconductor (CMOS) device including a P-type metal-oxide-semiconductor (PMOS) FinFET device and an N-type metal-oxide-semiconductor (NMOS) FinFET device. Embodiments will now be described with respect to particular examples including FinFET manufacturing processes. Embodiments, however, are not limited to the examples provided herein, and the ideas may be implemented in a wide array of embodiments. Thus, various embodiments may be applied to other semiconductor devices/processes, such as planar transistors, and the like. Further, some embodiments discussed herein are discussed in the context of devices formed using a gate-last process. In other embodiments, a gate-first process may be used.

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and more particularly to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel or any number of channels, such as a FinFET device, on account of its fin-like structure. One of ordinary skill may recognize other examples of semiconductor devices that may benefit from aspects of the present disclosure.

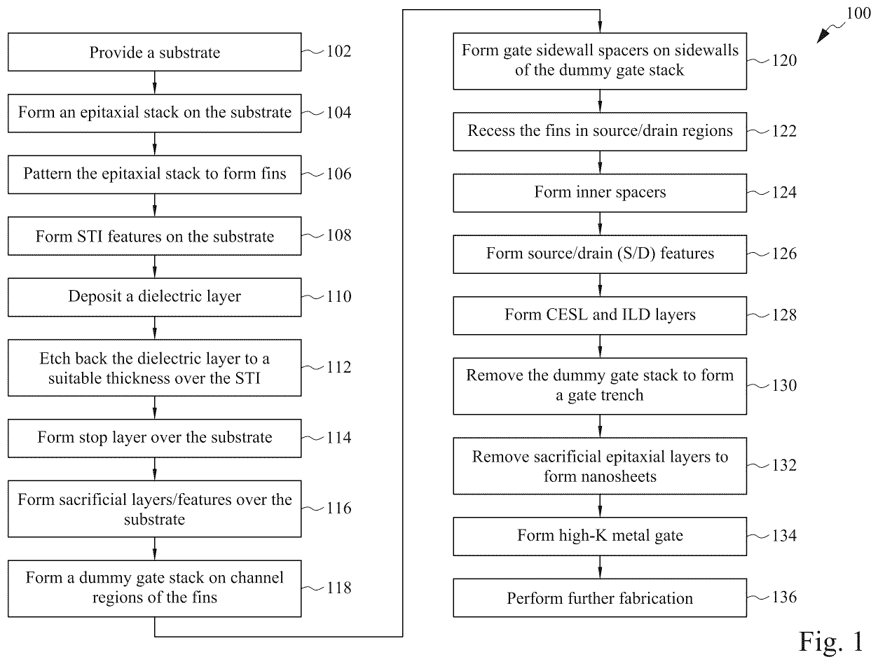

FIG. 1 is a flow chart depicting an example method 100 of semiconductor fabrication including fabrication of multi-gate devices. according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

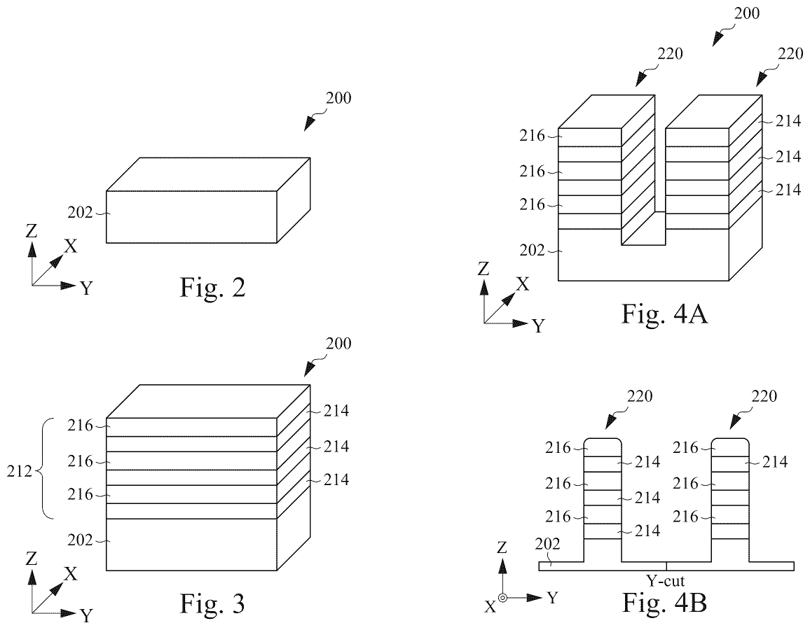

FIG. 1 is described in conjunction with FIGS. 2-3, 4A-4B, 5A-5C, 6A-6C, 7A-7C, 8A-8C, 9A-9D, 10A-10B, 11-12, 13A-13B, 14-15, and 16A-16B, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4B, 5A-5C, 6A-6C, 7A-7C, 8A-8C, 9A-9D, 10A-10B, 11-12, 13A-13B, 14-15, and 16A-16B, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a multi-gate device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming one an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{˜}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

At block 106, the example method 100 includes patterning the epitaxial stack to form semiconductor fins (also referred to as fins). Referring to the example of FIGS. 4A and 4B, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

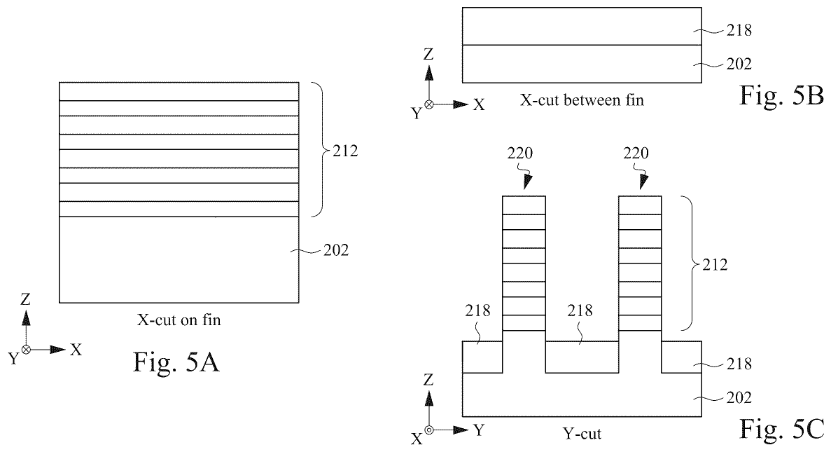

At block 108, the example method 100 includes forming STI (shallow trench isolation) features on the substrate. In various embodiments, the STI features are formed by filling trenches between adjacent fins with a dielectric material to form an isolation feature. Referring to the example of FIGS. 5A, 5B and 5C, in an embodiment of block 108, STI features 218 are deposited between adjacent fins 220. The STI features may include one or more dielectric layers. Suitable dielectric materials for the STI features may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. The deposited STI features are subsequently recessed to form shallow trench isolation (STI) features. Any suitable etching technique may be used to recess the isolation features including dry etching, wet etching, RIE, and/or other etching methods, and in an exemplary embodiment, an anisotropic dry etching is used to selectively remove the dielectric material of the isolation features without etching the fins.

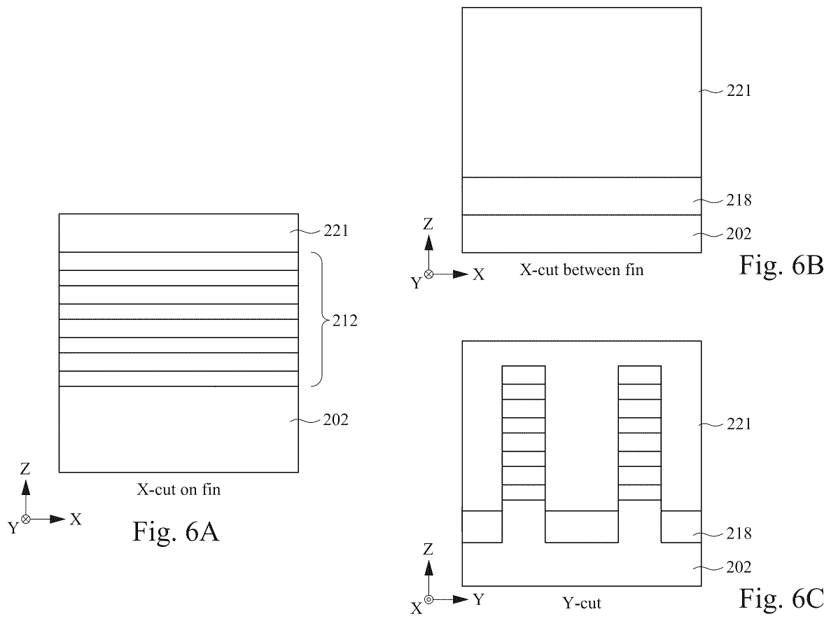

At block 110, the example method 100 includes depositing a dielectric layer over the substrate features. Referring to the example of FIGS. 6A, 6B, and 6C, in an embodiment of block 110, a dielectric layer 221 is depositing over the substrate 202. In various embodiments, the dielectric layer 221 is formed from Si-based material such as SiO, SiN, SiCN, SiON, SiOCN, and others. With the use of these materials, etching selectivity can be adjusted during metal gate replacement operations to make etching less lossy (e.g., lower STI loss). When metal fills the position with less loss, its capacitance effect can be reduced. In various embodiments, the dielectric layer 221 may be deposited using CVD, including LPCVD and PECVD, PVD, ALD, or other suitable processes.

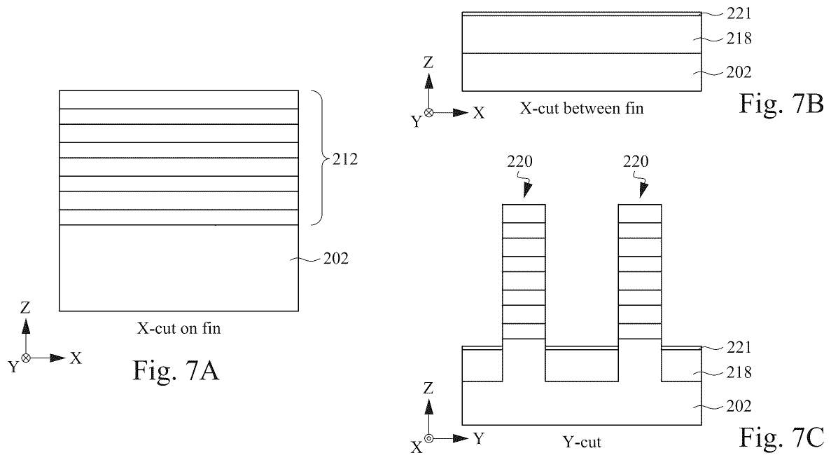

At block 112, the example method 100 includes etching back the dielectric layer to a suitable thickness over the STI features. Referring to the example of FIGS. 7A, 7B, and 7C, in an embodiment of block 112, the dielectric layer 221 has been etched back to a suitable thickness over the STI features 218. In various embodiments, etching back the dielectric layer 221 may be accomplished by various etching techniques such as wet etching and dry etching techniques. In various embodiments, the remaining dielectric layer 221 has a thickness of approximately 4 to approximately 7 nm. In various embodiments, if the remaining dielectric layer 221 has a thickness <4 nm, this can lead to excessive losses and capacitance effects. In various embodiments, if the remaining dielectric layer 221 has a thickness >7 nm, this can lead to problems (poor epitaxial) with the third layer of Si epitaxial growth.

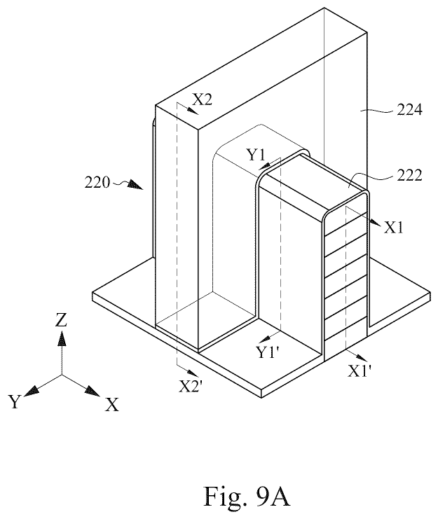

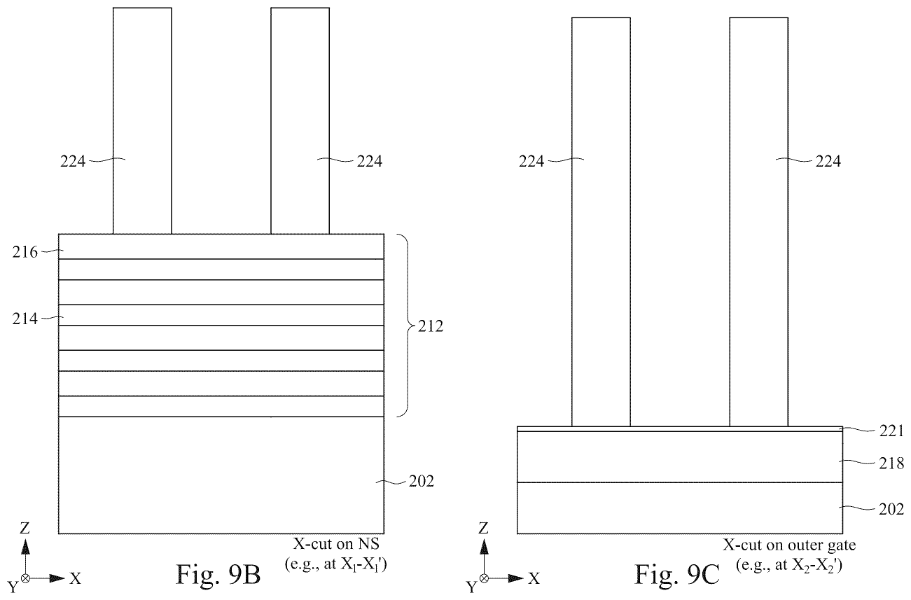

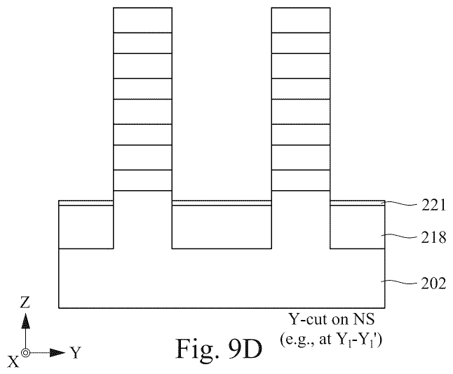

At block 114, the example method 100 includes forming a stop layer over the fins and substrate. In various embodiments, the stop layer is blanket deposited the over the fins 220 and the STI features 218. In various embodiments, the thickness of the stop layer 222 (shown in FIG. 9A) is in a range from about 1 nm to about 5 nm. In various embodiments, the stop layer 222 is subjected to a planarization operation. In various embodiments, the stop layer 222 may be deposited using CVD, including LPCVD and PECVD, PVD, ALD, or other suitable processes.

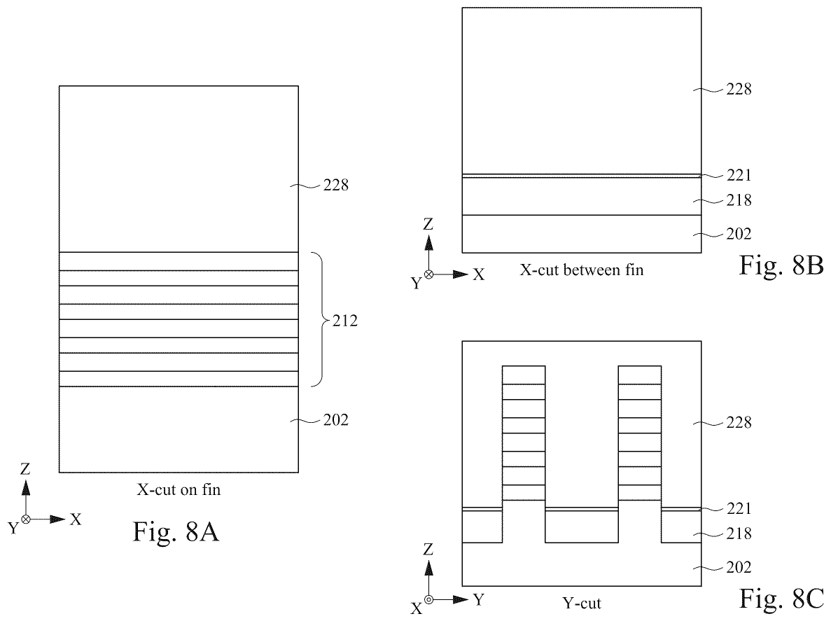

At block 116, the example method 100 includes forming one or more sacrificial layers/features over the substrate. Referring to the example of FIGS. 8A, 8B, and 8C, in an embodiment of block 116, a sacrificial gate dielectric layer (not shown) is blanket deposited over the stop layer 222, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

At block 118, the example method 100 includes patterning the one or more sacrificial layers/features to form a dummy gate structure on channel regions of the fins. Referring to the example of FIGS. 9A, 9B, 9C, and 9D, in an embodiment of block 118, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer (not shown) and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same. The dielectric layer 221 prevents or substantially eliminates loss of STI features 218 during dummy gate patterning operations.

The sacrificial gate structure 224 is subsequently removed as discussed with reference to block 130 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

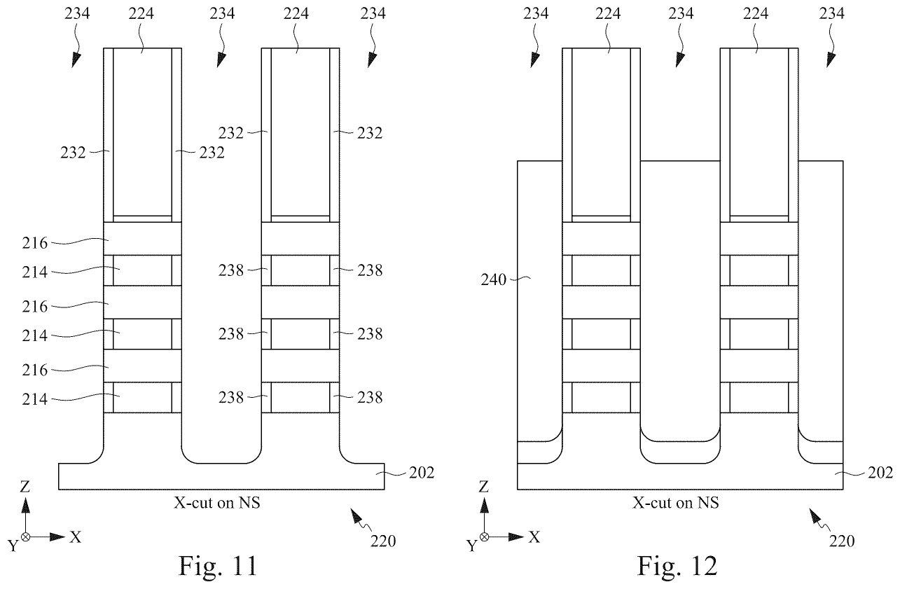

At block 120, the example method 100 includes forming gate sidewall spacers on sidewalls of the dummy gate stack. The gate sidewall spacers 232 (shown in FIG. 11) may include a dielectric material such as silicon oxide, silicon nitride, silicon carbide, silicon oxynitride, SiCN films, silicon oxycarbide, SiOCN films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

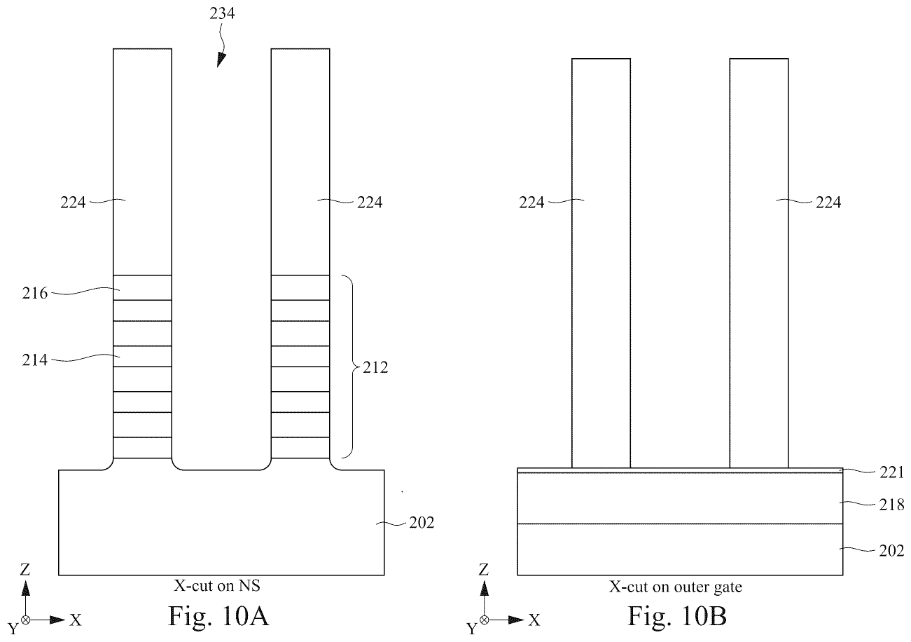

At block 122, the example method includes recessing the fins in the source drain/regions. Referring to the example of FIGS. 10A and 10B, in an embodiment of block 122, the fins in the source drain/regions are recessed. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

At block 124, the example method 100 Includes forming inner spacers. Forming inner spacers may include recessing sacrificial epitaxial layers (e.g., SiGe), depositing inner spacer material, and etching back inner spacer material. Referring to the example of FIG. 11, in an embodiment of block 124, gate sidewall spacers 232 and inner spacers 238 are depicted. The sacrificial epitaxial layers 214 have been etched back. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 124 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

The inner spacers 238 may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer can be formed by ALD or any other suitable method. After the inner spacer material layer is formed, an etching operation may be performed to partially remove the inner spacer material layer.

At block 126, the example method 100 includes forming source/drain (S/D) features. Referring to the example of FIG. 12, in an embodiment of block 126. Epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216, and separated from the sacrificial epitaxial layers 214 by the inner spacers 238.

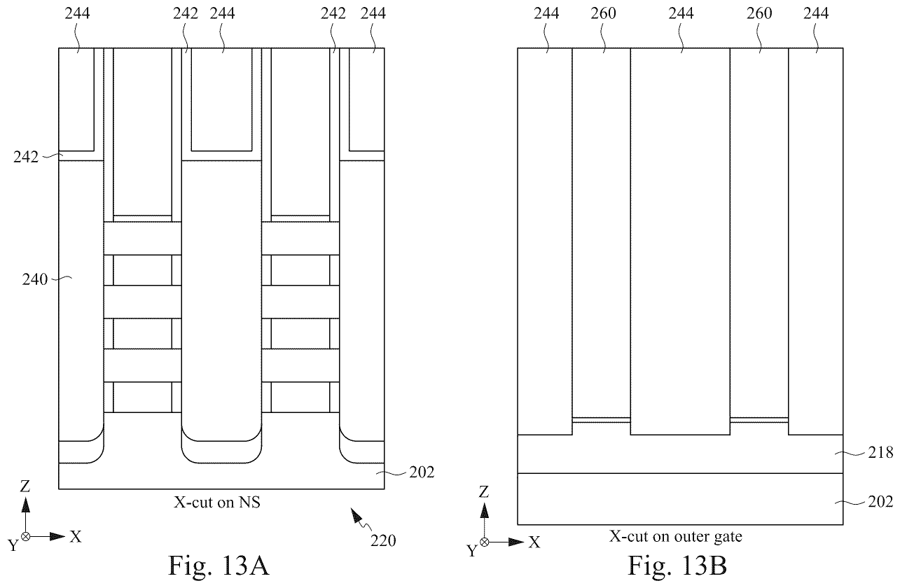

At block 128, the example method 100 includes forming CESL and ILD layers. Referring to the example of FIGS. 13A and 13B, in an embodiment of block 128, a contact etch stop layer (CESL) 242 is formed over the epitaxial S/D features 240 and an interlayer dielectric (ILD) layer 244 is formed over the CESL layer 242. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the device 200, such that the top surfaces of the sacrificial gate structure 224 are exposed.

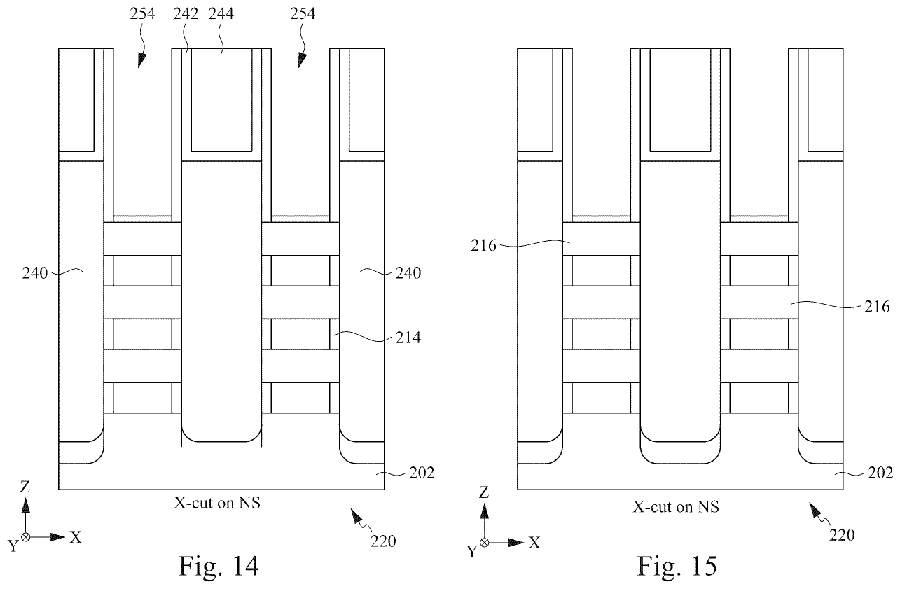

At block 130, the example method 100 includes removing the dummy gate stack to form a gate trench. Referring to the example of FIG. 14, in an embodiment of block 130, the sacrificial gate structure 224 has been removed to form a gate trench 254. The gate trench 254 exposes the fin 220 in the channel region(s). The ILD layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD layer 244 is an oxide, a wet etchant such as a TMAH solution can be used to selectively remove the sacrificial gate electrode layer. The sacrificial gate dielectric layer is thereafter removed using plasma dry etching and/or wet etching.

At block 132, the example method 100 includes removing the sacrificial epitaxial layers to form nanosheets. Referring to the example of FIG. 15, in an embodiment of block 132, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

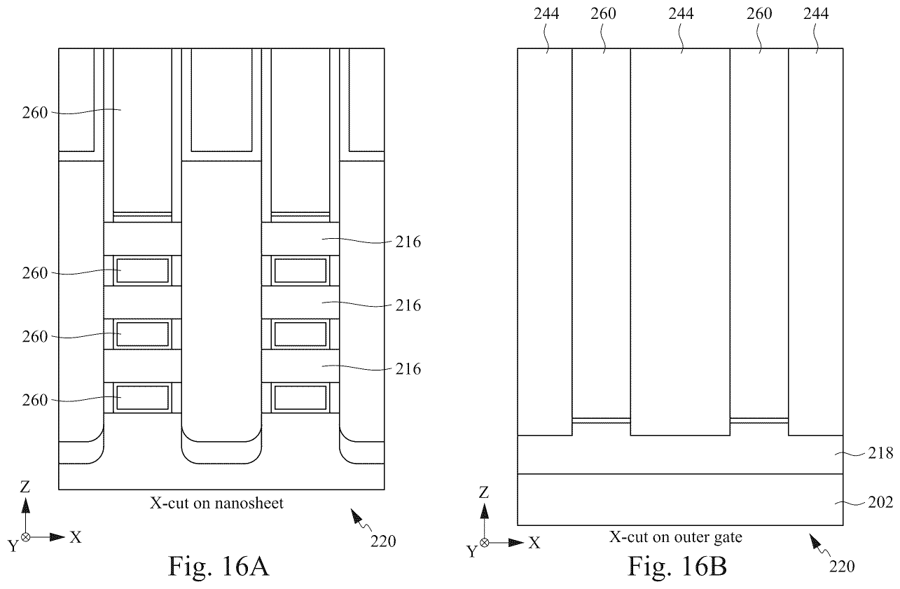

At block 134, the example method 100 includes forming high-K metal gate structures. Referring to the example of FIGS. 16A and 16B, in an embodiment of block 134, a gate structure 260 is formed. In various embodiments, the gate structure is the gate of a multi-gate transistor. In various embodiments, the gate structure is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layers. The high-K metal gate structures may include additional material layers.

At block 136, the example method 100 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

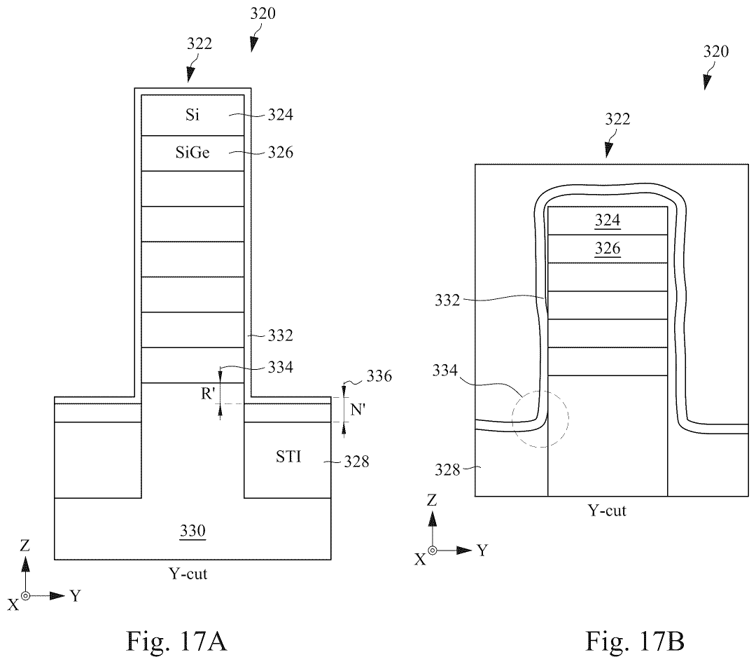

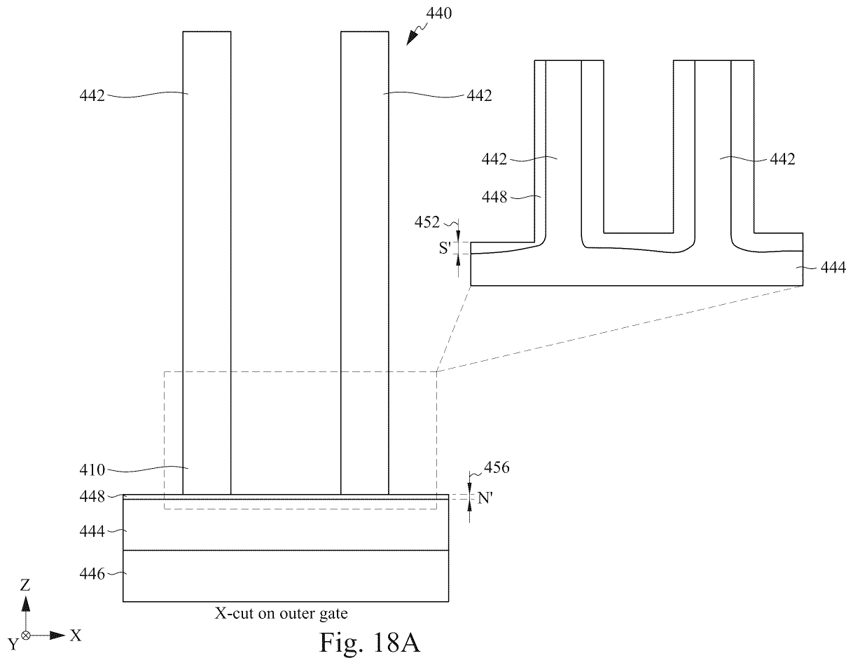

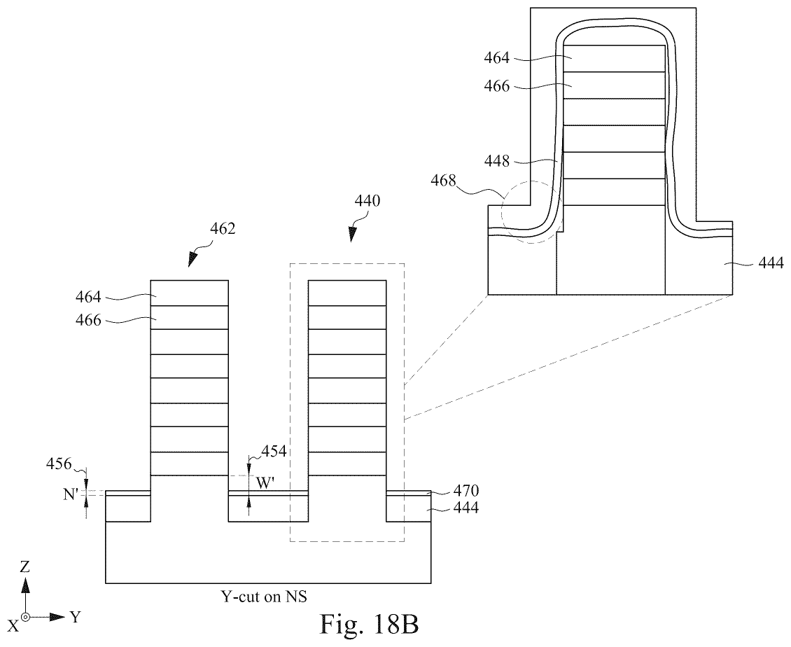

FIGS. 17A and 17B are schematic diagrams of an example semiconductor device 320 at a stage of fabrication after forming a stop layer. Depicted are a fin 322 that includes alternating channel epitaxial layers 324 and sacrificial epitaxial layers 326, STI features 328 deposited over a substrate 330 on opposite sides of the fin 322, dielectric material 336 deposited over the STI features 328, and a stop layer 332 deposited over the fin 322 and the dielectric material 336. The example semiconductor device 320 includes a height R′ (334) measured from the bottom of the sacrificial epitaxial layer 326 to the bottom of the stop layer 332, and a thickness N′ (338) of the dielectric material 336. Because a dielectric layer was interposed between the STI and the stop layer, lower STI loss was experienced during dummy gate patterning operations than would occur if the dielectric layer had not been interposed between the STI and the stop layer. In various embodiments, the height R′ is between approximately 2 nm to approximately 4 nm and the thickness N′ is between approximately 4 nm to approximately 7 nm. As illustrated in FIG. 18B, the stop layer 332 has a near right angle shape at the corner 334 where the stop layer 332 meets the STI features 328. Without the dielectric layer interposed between the STI and the stop layer, a height R measured from the bottom of the sacrificial epitaxial layer to the bottom of the stop layer may be in a range between approximately 10 nm to approximately 15 nm, and the stop layer may have a rounded shape at the corner where the stop layer meets the STI features.

FIGS. 18A and 18B are schematic diagrams depicting an example semiconductor device 440 at a stage of fabrication after dummy gate patterning. FIG. 18A is a schematic diagram depicting a cross section of an example semiconductor device 440 along the x-axis on the STI (outer gate). Depicted are a dummy gate 442 and STI features 444 deposited over a substrate 446. A height S′ (452) is defined between an inner gate stop layer 448 and a top of an outer gate dielectric 470. As illustrated, the stop layer 448 has a near right angle shape around the top of the STI features 444.

FIG. 18B is a schematic diagram depicting a cross section of the example semiconductor device 440 along the y-axis on a nanosheet. Depicted are a fin 462 that includes alternating channel epitaxial layers 464 and sacrificial epitaxial layers 466, STI features 444 deposited over the substrate 446 on opposite sides of the fin 462, and gate dielectric 470 deposited over the STI features 444. A height W′ (454) is defined between the bottom of a sacrificial epitaxial layer 466 and a top of outer gate dielectric 470. As illustrated, the stop layer 448 has a near right angle shape at the corner 468 where the stop layer 448 meets the STI features 444. A height N′ (456) is defined for the height of the dielectric material 470 that remains after dummy gate patterning operations. The dielectric material 470 prevents STI loss during dummy gate patterning operations. Because a dielectric layer was interposed between the STI and the stop layer, lower STI loss was experienced during dummy gate patterning operations. In various embodiments, S′ is 0 to approximately 2 nm. In various embodiments, W′ is approximately 7 to approximately 12 nm. In various embodiments, N′ is approximately 1 nm to approximately 4 nm. Without the dielectric layer interposed between the STI and the stop layer, the stop layer may have a rounded shape at the corner where the stop layer meets the STI features, a height S defined between an inner gate stop layer and an outer gate STI top may be approximately 3 nm to approximately 6 nm, and a height W defined between the bottom of a sacrificial epitaxial layer and an outer gate STI top may be approximately 16 to approximately 21 nm.

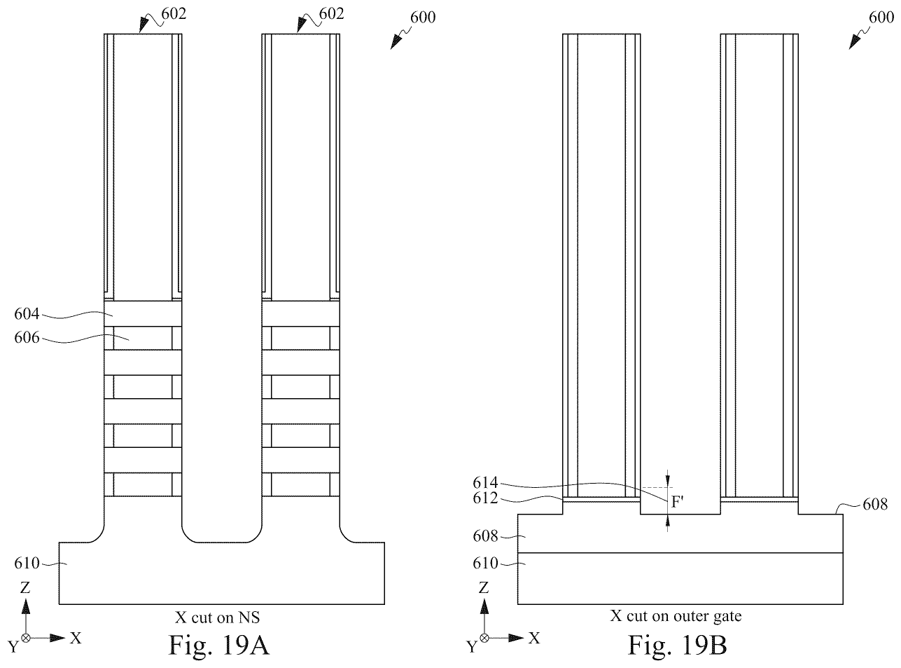

FIGS. 19A and 19B are schematic diagrams of another example semiconductor device 600 at a stage of fabrication after spacer deposition, S/D etch, and inner spacer deposition and etching. FIG. 19A depicts a cross section of the example semiconductor device 600 along the x-axis on a nano sheet. FIG. 19B depicts a cross section of the example semiconductor device 600 along the x-axis on the STI (outer gate). Depicted are fins 602 that includes alternating channel epitaxial layers 604 and sacrificial epitaxial layers 606, and STI features 608 deposited over a substrate 610. The example semiconductor device 600 includes a height F′ (614) measured from the inner gate stop layer 612 to the top of the outer gate STI 608. Because a dielectric layer was interposed between the STI and the stop layer, lower STI loss was experienced during dummy gate patterning operations. In various embodiments, the height F′ is between approximately 3 nm to approximately 10 nm. Without the dielectric layer interposed between the STI and the stop layer, a height F measured from the inner gate stop layer to the top of the outer gate STI may be between approximately 16 nm to approximately 30 nm.

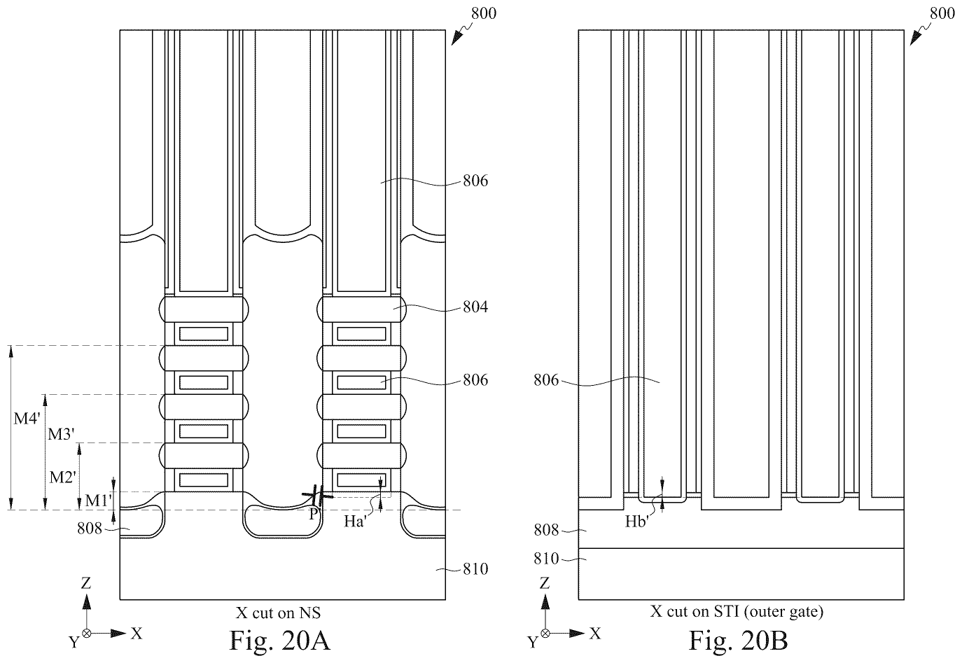

FIGS. 20A and 20B are schematic diagrams of an example semiconductor device 800 at a stage of fabrication after HK metal gate replacement. FIG. 20A depicts a cross section of a fin 802 of the example semiconductor device 800 along the x-axis on a nano sheet. FIG. 20B depicts a cross section of the example semiconductor device 800 along the x-axis on the STI (outer gate). Depicted are alternating nano sheets 804 and metal gate layers 806 over a substrate 810, and STI features 808 deposited over the substrate 810.

The example semiconductor device 800 includes a height M1′ measured from a bottom of a lowest nanosheet to a bottom of the CESL, a height M2′ measured from a bottom of a second lowest nanosheet to a bottom of the CESL, a height M3′ measured from a bottom of a third lowest nanosheet to a bottom of the CESL, and a height M4′ measured from a bottom of a fourth lowest nanosheet to a bottom of the CESL. The example semiconductor device 800 includes a height Ha′ (or metal depth) measured from a STI top to third level Si channel as seen from an x-cut on a nanosheet, a height Hb′ (or metal depth) measured from a STI top to metal bottom as seen from an x-cut on the STI from an outer gate perspective, a shortest distance P′ measured between a point in the S/D EPI to point on the metal bottom, and near right angle shape at a corner where the stop layer meets the STI features.

Because a dielectric layer was interposed between the STI and the stop layer, lower STI loss was experienced during metal gate replacement operations. In various embodiments, the height M1′ is between approximately 4 nm to approximately 6 nm, M2′ is between approximately 19 nm to approximately 21 nm, M3′ is between approximately 34 nm to approximately 36 nm, M4′ is between approximately 49 nm to approximately 51 nm, Ha′ is between approximately 2 nm to approximately 4 nm, Hb′ is between approximately 2 nm to approximately 4 nm, and P′ is between approximately 9 nm to approximately 12 nm. When the distances Ha′, Hb′, and/or P′ are shortened, the distance from EPI will become farther. The farther away, the less the capacitive effect. Because a dielectric layer was interposed between the STI and the stop layer, the distance P′ between the metal gate and the S/D EPI is longer leading to reduced capacitance between the metal gate and the metal drain.

Without the dielectric layer interposed between the STI and the stop layer, the example semiconductor device may include a height M1 measured from a bottom of a lowest nanosheet to a bottom of the CESL that may be between approximately 16 nm to approximately 30 nm, a height M2 measured from a bottom of a second lowest nanosheet to a bottom of the CESL that may be between approximately 31 nm to approximately 35 nm, a height M3 measured from a bottom of a third lowest nanosheet to a bottom of the CESL that may be between approximately 45 nm to approximately 50 nm, a height M4 measured from a bottom of a fourth lowest nanosheet to a bottom of the CESL that may be between approximately 61 nm to approximately 65 nm, and each additional nano sheet may add approximately 15 nm to the distance. Also, without the dielectric layer interposed between the STI and the stop layer, Ha may be between approximately 14 nm to approximately 18 nm, Hb may be between approximately 14 nm to approximately 18 nm, and P may be between approximately 3 nm to approximately 8 nm.

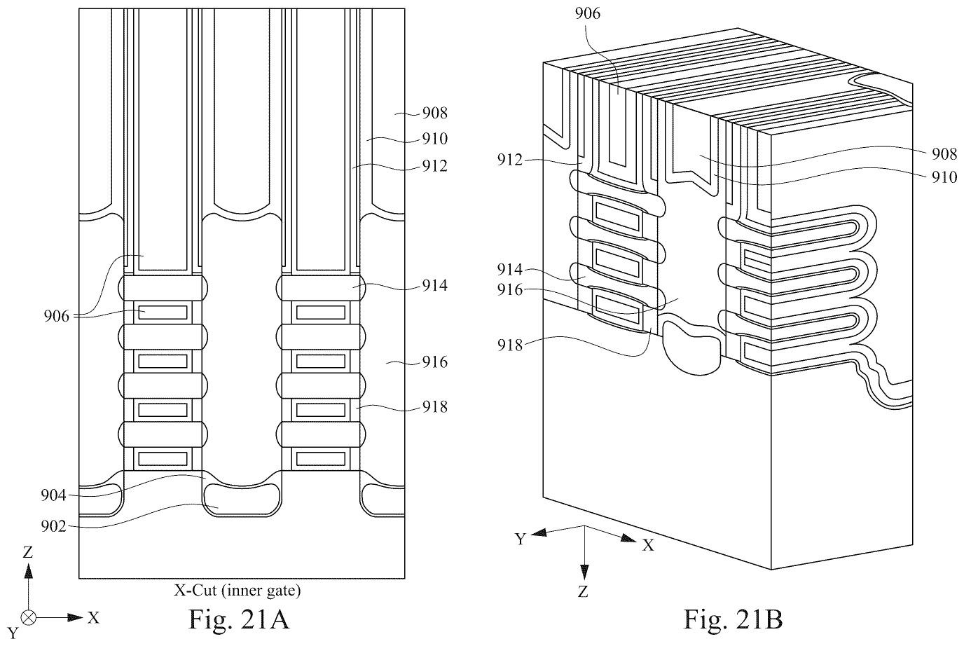

FIGS. 21A and 21B are schematic diagrams of an example semiconductor device, in accordance with various embodiments. FIG. 21B is a three dimensional portion of the example semiconductor device and FIG. 21A is a cross section of the example semiconductor device along an inner gate along the x-axis. Depicted are STI features 902 (e.g., Si-based SiO, SiN, SiCN, SiON, SiOCN), dielectric material 904 (e.g., Si-based SiO, SiN, SiCN, SiON, SiOCN), high K metal gate 906 (HK: e.g., HfO, TaN; Metal: e.g., W, Cu, Co), ILD 908, CESL 910, gate spacer 912 (e.g., SiCN, SiOCN, SiON, SiN), channel 914 (e.g., nano-sheet), S/D 916 (EPI), and inner spacers 918 (e.g., SiCN, SiOCN, SiON, SiN).

Improved systems, fabrication methods, fabrication techniques, and articles have been described. The described systems, methods, techniques, and articles can be used with a wide range of semiconductor devices including Gate-all-around FET (GAAFET/NSFET)/Fork-sheet/CFET/VFET/MOSFET.

In some aspects, the techniques described herein relate to a fabrication method, including: depositing a dielectric layer above shallow trench isolation (STI) features formed between a first fin and a second fin on a substrate that each include an epitaxial stack including at least one sacrificial epitaxial layer and at least one channel epitaxial layer, wherein dielectric layer reduces STI loss during subsequent etching operations; patterning a sacrificial gate stack on channel regions of the first fin; forming gate spacers, performing source/drain (S/D) etching operations on opposite sides of the sacrificial gate stack and forming inner gate spacers; forming an S/D region; forming a contact etch stop layer (CESL); and replacing the sacrificial gate stack with a metal gate.

In some aspects, the techniques described herein relate to a method, wherein the dielectric layer formed above the STI has a thickness of between 4 nm to 7 nm.

In some aspects, the techniques described herein relate to a method, wherein the dielectric layer formed is formed from a Silicon (Si) based dielectric material including at least one of SiN, SiCN, SiON, or SiOCN.

In some aspects, the techniques described herein relate to a method, wherein a height S′ is defined after sacrificial gate stack patterning operations between an inner gate stop layer and a top of an outer gate dielectric that is approximately 2 nm or less.

In some aspects, the techniques described herein relate to a method, wherein a height W′ is defined after sacrificial gate stack patterning operations between a bottom of a sacrificial epitaxial layer and a top of an outer gate dielectric that is approximately 7 nm to approximately 12 nm.

In some aspects, the techniques described herein relate to a method, wherein a height N′ of the dielectric layer that remains after sacrificial gate stack patterning operations is approximately 1 nm to approximately 4 nm.

In some aspects, the techniques described herein relate to a method, wherein a height F′ is defined after S/D etching operations between an inner gate stop layer to a top of an outer gate STI that is approximately 3 nm to approximately 10 nm.

In some aspects, the techniques described herein relate to a semiconductor structure, including: a fin including a plurality of nanosheets disposed over a substrate; a gate structure disposed over a channel region of the plurality of nanosheets; source/drain (S/D) features disposed on opposite sides of the channel region; and STI features disposed on opposite sides of the fin; wherein a metal depth of a bottom nanosheet of the plurality of nanosheets into the STI features is less than or equal to 4 nm.

In some aspects, the techniques described herein relate to a semiconductor structure, wherein the metal depth is between 2 nm to 4 nm.

In some aspects, the techniques described herein relate to a semiconductor structure, wherein a shortest distance between a bottom of the bottom nanosheet and the S/D features is greater than 8 nm.

In some aspects, the techniques described herein relate to a semiconductor structure, wherein a shortest distance between a bottom of the bottom nanosheet and the S/D features is between 9 nm to 12 nm.

In some aspects, the techniques described herein relate to a semiconductor structure, further including a contact etch stop layer (CESL) disposed on sidewalls of the gate structure, on sidewalls of an adjacent gate structure, and over STI features disposed between the gate structure and the adjacent gate structure, and wherein a first height measured from a bottom of the bottom nanosheet to a bottom of the CESL is 4 nm to 6 nm.

In some aspects, the techniques described herein relate to a semiconductor structure, further including a contact etch stop layer (CESL) disposed on sidewalls of the gate structure, on sidewalls of an adjacent gate structure, and over STI features disposed between the gate structure and the adjacent gate structure, and wherein a second height measured from a bottom of a second lowest nanosheet to a bottom of the CESL is 19 nm to 21 nm.

In some aspects, the techniques described herein relate to a fabrication method, including: depositing a dielectric layer above shallow trench isolation (STI) features formed between a first fin and a second fin on a substrate that each include an epitaxial stack including at least one sacrificial epitaxial layer and at least one channel epitaxial layer, wherein dielectric layer reduces STI loss during subsequent etching operations; patterning a sacrificial gate stack on channel regions of the first fin; forming a source/drain (S/D) region; forming a contact etch stop layer (CESL); and performing metal gate replacement operations thereby forming a metal gate including a plurality of nanosheets.

In some aspects, the techniques described herein relate to a method, wherein after metal gate replacement operations a shortest distance P′ between a point in the S/D region to a point on a bottom nanosheet of the metal gate is between approximately 9 nm to approximately 12 nm.

In some aspects, the techniques described herein relate to a method, wherein after metal gate replacement operations, a height Ha′ measured from an STI top to a metal bottom in a plane that intersects a nano sheet is between approximately 2 nm to approximately 4 nm.

In some aspects, the techniques described herein relate to a method, wherein after metal gate replacement operations, a height Hb′ measured from an STI top to a metal bottom in a plane outside of a nano sheet is between approximately 2 nm to approximately 4 nm.

In some aspects, the techniques described herein relate to a method, wherein after metal gate replacement operations, a height M1′ measured from a bottom of a lowest nanosheet to a bottom of the CESL is between approximately 4 nm to approximately 6 nm.

In some aspects, the techniques described herein relate to a method, wherein after metal gate replacement operations, a height M2′ measured from a bottom of a second lowest nanosheet to a bottom of the CESL is between approximately 19 nm to approximately 21 nm.

In some aspects, the techniques described herein relate to a method, wherein after metal gate replacement operations, a height M3′ measured from a bottom of a third lowest nanosheet to a bottom of the CESL is between approximately 34 nm to approximately 36 nm.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A fabrication method, comprising:
depositing a dielectric layer above shallow trench isolation (STI) features formed between a first fin and a second fin on a substrate that each include an epitaxial stack comprising at least one sacrificial epitaxial layer and at least one channel epitaxial layer, wherein dielectric layer reduces STI loss during subsequent etching operations;
patterning a sacrificial gate stack on channel regions of the first fin;
forming gate spacers, performing source/drain (S/D) etching operations on opposite sides of the sacrificial gate stack and forming inner gate spacers;
forming a source/drain (S/D) region;
forming a contact etch stop layer (CESL); and
replacing the sacrificial gate stack with a metal gate.

2. The method of claim 1, wherein the dielectric layer formed above the STI has a thickness of between 4 nm to 7 nm.

3. The method of claim 1, wherein the dielectric layer formed is formed from a Silicon (Si) based dielectric material comprising at least one of SiN, SiCN, SiON, or SiOCN.

4. The method of claim 1, wherein a height S′ is defined after sacrificial gate stack patterning operations between an inner gate stop layer and a top of an outer gate dielectric that is approximately 2 nm or less.

5. The method of claim 1, wherein a height W′ is defined after sacrificial gate stack patterning operations between a bottom of a sacrificial epitaxial layer and a top of an outer gate dielectric that is approximately 7 nm to approximately 12 nm.

6. The method of claim 1, wherein a height N′ of the dielectric layer that remains after sacrificial gate stack patterning operations is approximately 1 nm to approximately 4 nm.

7. The method of claim 1, wherein a height F′ is defined after S/D etching operations between an inner gate stop layer to a top of an outer gate STI that is approximately 3 nm to approximately 10 nm.

8. A semiconductor structure, comprising:
a plurality of nanosheets disposed over a substrate;
a gate structure disposed over a channel region of the plurality of nanosheets;
source/drain (S/D) features disposed on opposite sides of the channel region; and
STI features disposed on the substrate;
wherein a metal depth of a bottom nanosheet of the plurality of nanosheets into the STI features is less than or equal to 4 nm.

9. The semiconductor structure of claim 8, wherein the metal depth is between 2 nm to 4 nm.

10. The semiconductor structure of claim 8, wherein a shortest distance between a bottom of the bottom nanosheet and the S/D features is greater than 8 nm.

11. The semiconductor structure of claim 8, wherein a shortest distance between a bottom of the bottom nanosheet and the S/D features is between 9 nm to 12 nm.

12. The semiconductor structure of claim 8, further comprising a contact etch stop layer (CESL) disposed on sidewalls of the gate structure, on sidewalls of an adjacent gate structure, and over STI features disposed between the gate structure and the adjacent gate structure, and wherein a first height measured from a bottom of the bottom nanosheet to a bottom of the CESL is 4 nm to 6 nm.

13. The semiconductor structure of claim 8, further comprising a contact etch stop layer (CESL) disposed on sidewalls of the gate structure, on sidewalls of an adjacent gate structure, and over STI features disposed between the gate structure and the adjacent gate structure, and wherein a second height measured from a bottom of a second lowest nanosheet to a bottom of the CESL is 19 nm to 21 nm.

14. A fabrication method, comprising:
depositing a dielectric layer above shallow trench isolation (STI) features formed adjacent to a fin on a substrate, wherein dielectric layer reduces STI loss during subsequent etching operations;
patterning a sacrificial gate stack on the fin;
forming a source/drain (S/D) region;
forming a contact etch stop layer (CESL); and
performing metal gate replacement operations thereby forming a metal gate comprising a plurality of nanosheets.

15. The method of claim 14, wherein after metal gate replacement operations a shortest distance P′ between a point in the S/D region to a point on a bottom nanosheet of the metal gate is between approximately 9 nm to approximately 12 nm.

16. The method of claim 14, wherein after metal gate replacement operations, a height Ha′ measured from an STI top to a metal bottom in a plane that intersects a nano sheet is between approximately 2 nm to approximately 4 nm.

17. The method of claim 14, wherein after metal gate replacement operations, a height Hb′ measured from an STI top to a metal bottom in a plane outside of a nano sheet is between approximately 2 nm to approximately 4 nm.

18. The method of claim 14, wherein after metal gate replacement operations, a height M1′ measured from a bottom of a lowest nanosheet to a bottom of the CESL is between approximately 4 nm to approximately 6 nm.

19. The method of claim 14, wherein after metal gate replacement operations, a height M2′ measured from a bottom of a second lowest nanosheet to a bottom of the CESL is between approximately 19 nm to approximately 21 nm.

20. The method of claim 14, wherein after metal gate replacement operations, a height M3′ measured from a bottom of a third lowest nanosheet to a bottom of the CESL is between approximately 34 nm to approximately 36 nm.
